(19) United States
(12) Patent Application Publication
(10) Pub. No.: US 2007/0195548 A1
(43) Pub. Date: Aug. 23, 2007

(54) Light Emitting Panel for Medical Applications

(75) Inventor: Sean Xiaolu Wang, Wilmington, DE (US)

Correspondence Address: BWT PROPERTY, INC., 19 SHEA WAY, SUITE 301, NEWARK, DE, 19713, US

(73) Assignee: BWT PROPERTY, INC., Newark, DE (US)

(21) Appl. No.: 11/675,668

(22) Filed: Feb. 16, 2007

Related U.S. Application Data
(60) Provisional application No. 60/766,902, filed on Feb. 17, 2006.

(51) Int. Cl. H01L 33/00

(52) U.S. Cl. 362/555

(57) ABSTRACT

A light emitting panel is disclosed for medical applications including photodynamic therapy and photo bio-stimulation. The light emitting panel utilizes high intensity light emitting diodes (LEDs) as its light source and side-emitting optical fibers for light delivery.

### REFERENCE TO RELATED APPLICATIONS

This application claims an invention which was disclosed in Provisional Patent Application No. 60/766,902, filed Feb. 17, 2006, entitled “Light Emitting Panel for Medical Applications”. The benefit under 35 USC §119(e) of the above mentioned U.S. Provisional Applications is hereby claimed, and the aforementioned application is hereby incorporated herein by reference.

### FIELD OF THE INVENTION

This invention generally relates to a light emitting panel, and more specifically to a light emitting panel for medical applications.

### BACKGROUND

Photo-therapy relates to those treatment methods that utilize light to achieve their healing effects. The light treatment may be applied solely for bio-stimulation or used in combination with certain photo-sensitive drugs to selectively target a tissue. The majority of photo-therapy methods employ lasers as their light sources. However, the laser light source is generally very expensive and requires certain skills for the practitioner to handle due to safety issues. Recently, it has been taught that light emitting diode (LED) light sources can be used for photo-modulation of living cells by McDaniel in U.S. Pat. No. 6,663,659. In the McDaniel patent, a plurality of low intensity LEDs are assembled into a multi-panel structure for direct illumination of a target tissue, which will exhibit bio-activation or bio-inhibition according to the wavelength and dosage of the light source. One drawback of the McDaniel approach is that a large number of LEDs (ranging from 100 to 1000 per panel) are required to build the light emitting panel. This high packing density may present a challenge for dissipation of the heat generated by the LEDs. In U.S. Pat. Nos. 5,568,964 and 6,755,547, Parker et al. disclose a variety of light emitting panels where the light sources are remotely located from the panel. The disclosed light emitting panels are composed of woven fiber fabrics or plastic plates with roughened surfaces. The light is delivered from the light source to the light emitting panel through optical fibers or waveguides and emits from the micro-bended fibers or the roughed surfaces for illumination purposes. These kind of light panels do not suffer from the heat dissipation problem. However, only a small portion of the light can be delivered from the light source to the lighting emitting panel due to low LED-to-waveguide coupling efficiency. The coupling efficiency problem will be even worse for those newly developed high intensity LEDs, which generally have much larger light emitting areas. There thus exists a need in photo-therapy applications for a light emitting panel that has a remotely located light source to avoid heat dissipation problem and in the mean time maintains a high light emitting efficiency.

### SUMMARY OF THE INVENTION

It is one goal of the present invention to provide a flexible panel-like light emitting apparatus for photo-therapy applications, wherein the light sources are remotely located from the light emitting panel to avoid heat dissipation problem. In one preferred embodiment, the light emitting panel is composed of side-emitting optical fibers assembled into a panel-like structure. The fiber based panel is flexible to cover any complex contours of the target object. The side-emitting fibers are connected with the light sources through standard end-emitting optical fibers.

It is another goal of the present invention to reduce the number of light sources used in the light emitting apparatus. The goal is fulfilled by adopting recently developed high intensity LEDs with output power of more than an order of magnitude higher than those of conventional low-intensity LEDs.

It is yet another goal of the present invention to optimize the LED-to-fiber coupling stage so that a high percentage of the light emitted by the LED is delivered into the side-emitting fiber.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 illustrates the structure of the light emitting panel.

FIG. 2 illustrates the schematic design of the LED-to-fiber coupling stage.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a light emitting panel for medical applications. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

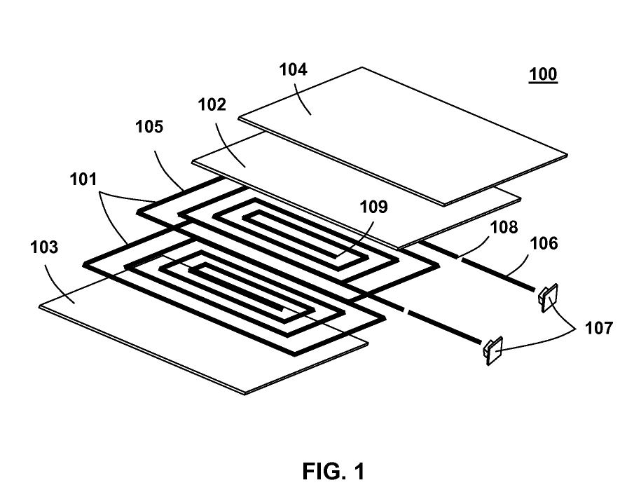

In one preferred embodiment of the present invention as shown in FIG. 1, the light emitting panel 100 comprises four layers: a light emitting layer 101, a holographic diffusion layer 102, a reflection layer 103, and a transparent cover layer 104. The light emitting layer 101 comprises one or more side-emitting optical fibers 105, which are coiled to form a panel-like structure. The side-emitting fiber 105 comprises a diffusive interface between its core and cladding region. The roughness of the diffusive interface is controlled so that a desired portion of the light in the core region is refracted to emit from the side surface of the fiber. A section of common end-emitting optical fiber 106 is employed to deliver the light from the LED light source 107 to the proximal end 108 of the side-emitting fiber 105. The distal end 109 of the side-emitting fiber 105 is reflection coated to prevent unwanted light leakage and further increase the light emitting efficiency of the side-emitting fiber 105. The holographic diffusion layer 102 is used to homogenize the light beam emitted from the light emitting layer 101. One example of such a holographic diffuser can be found in U.S. Pat. No. 6,446,467 by Lieberman et al., which is hereby incorporated by reference. The holographic diffuser features an ultra-high transmittance of 85-90% in comparison with conventional frost glass diffusers. The reflection layer 103 is placed under the light emitting layer 101 to convert the downward light emission into upward light emission. The light emitting panel is flexible in nature. Thus it can be applied to any body parts of the patient with any complex contours.

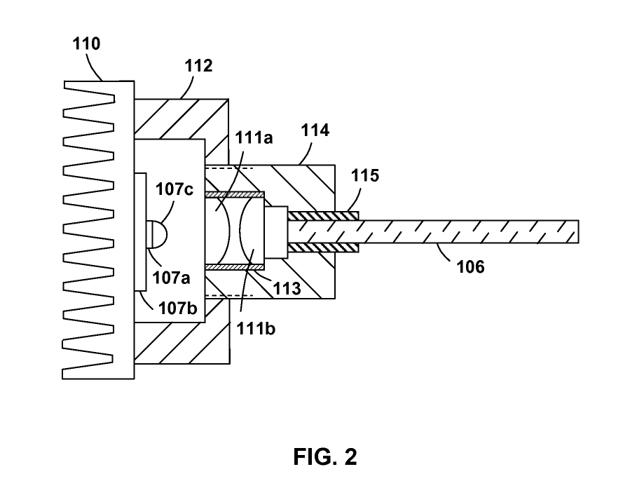

A more detailed illustration of the LED-to-fiber coupling stage is shown in FIG. 2. The LED 107 comprises an LED chip 107a surface-mounted on a thermal conductive substrate 107b. This chip-on-board (COB) package provides better heat dissipation for the LED chip 107a. Thus it allows a larger light emitting surface and a higher drive current for the LED chip 107a to increase its output power. It also leads to long lifetime as well as wavelength and intensity stability. An epoxy dome lens 107c coated on the surface of the LED chip 107a is used to control its radiation pattern. The LED 107 may further comprise a reflective cup (not shown in the figure) for better light collection efficiency. The whole LED module is mounted on an aluminum heat sink 110 for improved heat dissipation. The light emitted from the LED 107 is coupled into an end-emitting optical fiber 106 through a lens set 111. The numerical aperture (NA) and core diameter of the end-emitting optical fiber 106 are selected to match with the divergence angle and diameter of the LED beam that emitted from the lens set 111 for effectively collecting the LED light. The coupling lens set 111 comprises two pieces of single lens 111a and 111b, which are designed to have a large numerical aperture (F/1.0) and a small aberration to achieve high coupling efficiency. In this embodiment, a high LED-to-fiber light coupling efficiency of greater than 40 percent (>40%) is achieved. The LED 107, the lens set 111 and the fiber 106 are assembled together using fixture 112, 113, 114 and 115 to improve the mechanical and thermal stability of the coupling stage.

In the foregoing specification, specific embodiments of the present invention have been described. However, one of ordinary skill in the art appreciates that various modifications and changes can be made without departing from the scope of the present invention as set forth in the claims below. For example, with the advance of semiconductor technology, higher intensity LEDs will be readily available. Thus the number of LEDs used in the photo-therapy apparatus can be further reduced. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A light emitting panel for medical applications including but not limited to photodynamic therapy and photo bio-stimulation, the light emitting panel comprising:
at least one high intensity light emitting diode (LED) light source; and
at least one side-emitting optical fiber coiled to form a panel-like structure, wherein the side-emitting fiber collects light from said LED light source and emits the collected light along a side surface of the side-emitting fiber.

2. The light emitting panel of claim 1, further comprising a section of end-emitting fiber between the LED light source and the side-emitting fiber for light delivery.

3. The light emitting panel of claim 2, wherein the numerical aperture and the core diameter of the side-emitting fiber and the end-emitting fiber match with the beam divergence angle and the size of the LED light source, respectively for efficient light collection.

4. The light emitting panel of claim 1, further comprising an optical diffuser to homogenize the light emitted by the side-emitting fiber;

5. The light emitting panel of claim 1, further comprising a reflection member to reflect a portion of the light emitted from the side-emitting fiber from one direction into the opposite direction.

6. The light emitting panel of claim 1, further comprising a transparent cover.
